(19) United States
(12) Patent Application Publication
(10) Pub. No.: US 2010/0301393 A1
(43) Pub. Date: Dec. 2, 2010

(54) FIELD EFFECT TRANSISTOR AND MANUFACTURING METHOD THEREFOR

(76) Inventor: Nobuaki TERAGUCHI, Osaka (JP)

Correspondence Address: BIRCH STEWART KOLASCH & BIRCH, PO BOX 747, FALLS CHURCH, VA, 22040-0747, US

(21) Appl. No.: 12/788,872

(22) Filed: May 27, 2010

(30) Foreign Application Priority Data
May 28, 2009 (JP) 2009-128802

(51) Int. Cl. H01L 29/772; H01L 21/20

(52) U.S. Cl. 257/192; 438/478; 257/E29.242; 257/E21.09

(57) ABSTRACT

There is provided a field effect transistor of a normally-OFF operation having a low contact resistance and capable of avoiding increases in on-resistance and maintaining high channel mobility. In this field effect transistor, a thin-layer portion 6a of an AlGaN barrier layer 6, which is formed on V defects 13 of a second GaN layer 4 and on non-grown regions G1 of a third GaN layer 5 adjoining the V defects 13, can be made thinner than a flat portion 6b without etching. Therefore, increases in the on-resistance can be avoided without causing degradation of the channel mobility due to etching damage.

### TECHNICAL FIELD

The present invention relates to a field effect transistor formed from a nitride-related group III-V compound semiconductor and, in particular, to a normally-OFF type field effect transistor and a manufacturing method therefor.

### BACKGROUND ART

Conventionally, in an AlGaN/GaN heterostructure field effect transistor (HFET) using a nitride-based group III-V compound semiconductor, a C-plane (a flat plane vertical to a C-axis meaning a longitudinal direction of crystals) of a nitride-based group III-V compound semiconductor having a wurtzite structure is set parallel to a substrate surface. Due to this, electrons are induced by a piezo effect or spontaneous polarization, so that a two-dimensional electron gas (2DEG) is formed at an AlGaN/GaN interface. As a result, the transistor is referred to as normally-ON type transistor because applying a voltage to between its source and drain causes a drain current to flow through even when its gate voltage is zero.

In this connection, since normally-OFF type transistors, which involve no flow of drain current with a gate voltage of zero, are more desirable from the viewpoint of applications to general circuits, trials of some methods for the normally-OFF type have been made.

More specifically, Patent Literature 1 (JP 2000-277724 A) discloses a technique that an AlGaN layer under the gate electrode is provided as a thin layer by dry etching to adjust the quantity of 2DEG for implementation of the normally-OFF type.

Also, Non Patent Literature 1 (IEICE Technical Report ED 2005-205, MW 2005-159, pp. 35-39 (2006-1)) discloses a technique for implementation of the normally-OFF type with the use of a nonpolar plane of the wurtzite structure yielding no piezo effect or spontaneous polarization.

Also, Non Patent Literature 2 (phys. stat. sol. (a) Vol. 204, No. 6 pp. 2064-2067 (2007)) discloses a technique for implementation of the normally-OFF type with the use of a MIS (Metal Insulator Semiconductor)-structure transistor using no AlGaN/GaN heterostructure similar to that of Si MOS transistors.

In this connection, how to achieve the following two points (1), (2) matters for the normally-OFF type implementation:

(1) avoiding increases in the on-resistance; and

(2) maintaining high channel mobility.

In this regard, with the technique of Patent Literature 1, although the presence of 2DEG in the source/drain region makes it possible to avoid increases in the on-resistance in a contact region, yet there occurs a decrease in 2DEG in a channel region as well as a decrease in channel mobility caused by damage of reducing the thickness of a layer due to dry etching, resulting in occurrence of increases in the on-resistance.

Also, with the use of the nonpolar plane of the wurtzite structure (e.g., a-plane or m-plane) as in the technique of Non Patent Literature 1, there is a need for doping to be done in the AlGaN layer to cause carriers as in the case of the AlGaAs/GaAs structure. In this case, although the doping concentration of the AlGaN layer has to be increased in order to reduce the contact resistance of the source and the drain, yet increasing the doping concentration too much would cause the gate leak current to increase.

Still also, the technique of Non Patent Literature 2 has a problem that the channel mobility is lower than that in cases where 2DEG is formed, it is quite hard to reduce the on-resistance.

As shown above, it can be found quite difficult to implement the normally-OFF type transistor as it is low in contact resistance and keeps high channel mobility.

### SUMMARY OF INVENTION

### Technical Problem

Accordingly, an object of the present invention is to provide a field effect transistor of normally-OFF operation which is low in contact resistance and enabled to avoid increases in on-resistance and keep high channel mobility.

### Solution to Problem

In order to achieve the above object, the present invention provides a field effect transistor comprising:

a substrate having surface-processed portions formed at predetermined places in a surface thereof;

a buffer layer formed on the substrate;

a first nitride-based group III-V compound semiconductor layer which is formed on the buffer layer and which has dislocations generated at places corresponding to the surface-processed portions but has no V defects that are V-shaped non-grown regions whose nuclei are given by the dislocations;

a second nitride-based group III-V compound semiconductor layer formed on the first nitride-based group III-V compound semiconductor layer and having V defects that are V-shaped non-grown regions whose nuclei are given by the dislocations;

a third nitride-based group III-V compound semiconductor layer which is formed on the second nitride-based group III-V compound semiconductor layer so that the V defects are not buried thereby and which has non-grown regions adjacent to the V defects but has no additional V defects other than the V defects; and

a fourth nitride-based group III-V compound semiconductor layer which is formed on the third nitride-based group III-V compound semiconductor layer and which has a thin-layer portion formed along the V defects and the non-grown regions adjacent to the V defects, and a flat portion adjoining the thin-layer portion and formed outside the V defects and being thicker than the thin-layer portion, wherein

the first to third nitride-based group III-V compound semiconductor layers constitute a channel layer, the fourth nitride-based group III-V compound semiconductor layer constitutes a barrier layer, and the third nitride-based group III-V compound semiconductor layer and the fourth nitride-based group III-V compound semiconductor layer constitute a heterojunction.

According to the field effect transistor of this invention, in the third nitride-based group III-V compound semiconductor layer in a vicinity of an interface of the heterojunction between the channel layer and the barrier layer, the third nitride-based group III-V compound semiconductor layer forming part of the channel layer, a two-dimensional electron gas that depends on thickness and composition of the flat portion is formed in a region facing the flat portion of the barrier layer. Meanwhile, in regions facing the thin-layer portion of the barrier layer out of the second and third nitride-based group III-V compound semiconductor layers that form part of the channel layer, the two-dimensional electron gas is scarcely formed. Therefore, a field effect transistor of the normally-OFF operation can be realized by forming a gate electrode on the thin-layer portion out of the barrier layer.

Also, the thin-layer portion of the barrier layer, which is formed on the V defects and the non-grown regions adjacent to the V defects, can be made thinner than the flat portion without etching. Therefore, according to this invention, increases in the on-resistance can be avoided without causing degradation of the channel mobility due to etching damage. In addition, the thickness of the thin-layer portion of the barrier layer is not more than 50% of the thickness of the flat portion as an example.

In an embodiment, the V defects are arrayed with regularity.

According to this embodiment, it is easily achievable to locate the V defects concentratedly under the gate electrode.

An embodiment further comprises a gate electrode formed on the V defects arrayed with regularity.

According to this embodiment, since the gate electrode is formed on the thin-layer portion on the V defects out of the barrier layer, a field effect transistor of the normally-OFF operation can be realized.

An embodiment further comprises an insulating film formed between the fourth nitride-based group III-V compound semiconductor layer and the gate electrode.

According to this embodiment, the pinchoff voltage can be increased as compared with cases where no insulating film is formed. Therefore, this embodiment is suitable for circuit applications. In one example, whereas the pinchoff voltage is about 0 V with no insulating film formed, forming the insulating film allows the pinchoff voltage to be set to about +2 V to +3 V.

In another aspect, the invention provides a field effect transistor manufacturing method comprising the steps of:

forming a mask pattern on a substrate with resist or a material having etching-resistant property;

forming protrusive surface-processed portions at predetermined portions of the substrate by etching portions out of the substrate that are not covered with the mask pattern;

subsequently forming a buffer layer on the substrate;

making growth of a first nitride-based group III-V compound semiconductor layer that constitutes a channel layer on the buffer layer under such a growth temperature condition that dislocations are generated from places corresponding to the protrusive surface-processed portions while V defects that are V-shaped non-grown regions whose nuclei are given by the dislocations are not generated;

making growth of a second nitride-based group III-V compound semiconductor layer to constitute a channel layer under such a growth temperature condition that the V defects are generated on the first nitride-based group III-V compound semiconductor layer;

making growth of a third nitride-based group III-V compound semiconductor layer to constitute a channel layer on the second nitride-based group III-V compound semiconductor layer under such a growth temperature condition that the V defects of the second nitride-based group III-V compound semiconductor layer are not buried while non-grown regions adjacent to the V defects are generated but additional V defects other than the V defects are not generated; and

forming, on the third nitride-based group III-V compound semiconductor layer, a fourth nitride-based group III-V compound semiconductor layer which becomes a barrier layer having a thin-layer portion formed along the V defects and the non-grown regions adjacent to the V defects, and a flat portion adjoining the thin-layer portion and formed outside the V defects and being thicker than the thin-layer portion, and which constitutes a heterojunction in combination with the third nitride-based group III-V compound semiconductor layer.

According to the field effect transistor manufacturing method of this invention, dislocations due to the protrusive surface-processed portions formed by etching the substrate with the mask pattern are formed in the first nitride-based group III-V compound semiconductor layer, V defects whose nuclei are given by the dislocations are formed in the second nitride-based group III-V compound semiconductor layer, and non-grown regions adjacent to the V defects are formed in the third nitride-based group III-V compound semiconductor layer. Also, the thin-layer portion of the barrier layer, which is formed on the V defects and the non-grown regions adjacent to the V defects, can be made thinner than the flat portion without etching, so that the channel mobility is never degraded. Further, in regions facing the barrier layer out of the second and third nitride-based group III-V compound semiconductor layers that form part of the channel layer, the two-dimensional electron gas is scarcely formed. Therefore, a field effect transistor of the normally-OFF operation capable of maintaining high channel mobility can be realized by forming a gate electrode on the thin-layer portion out of the barrier layer.

In an embodiment, a process of etching the substrate is implemented by dry etching or wet etching, or a combination of dry etching and wet etching.

According to this embodiment, depending on the material of the substrate, if the substrate allows wet etching to be done thereon, wet etching is performed, and if wet etching is hard to do, dry etching is performed. It is also allowable to apply both dry etching and wet etching in combination to make use of their features.

In an embodiment, given that the substrate is made from a hard-to-wet etch material, the substrate is etched by dry etching.

According to this embodiment, when the substrate is made from a nitride-based group III-V compound semiconductor layer of sapphire, silicon carbide (SiC) or GaN, to which wet etching with solution is hard to apply, adopting dry etching makes it easily achievable to do etching of the substrate.

In an embodiment, an etching gas used for the dry etching is a chlorine-related gas.

According to this embodiment, using a chlorine-related gas (chlorine, silicon chloride, boron chloride, etc.) as the etching gas for dry etching makes it possible to implement effective etching for the substrate made from a material which is difficult to wet etch with solution.

In another aspect, the invention provides a field effect transistor manufacturing method comprising the steps of:

patterning a mask material for selective growth on a substrate to form surface-processed portions of the patterned mask material at predetermined places on the substrate;

subsequently forming a buffer layer on the substrate;

making growth of a first nitride-based group III-V compound semiconductor layer that constitutes a channel layer on the buffer layer under such a growth temperature condition that dislocations are generated from places corresponding to the surface-processed portions while V defects that are V-shaped non-grown regions whose nuclei are given by the dislocations are not generated;

making growth of a second nitride-based group III-V compound semiconductor layer to constitute a channel layer on the first nitride-based group III-V compound semiconductor layer under such a growth temperature condition that the V defects are generated;

making growth of a third nitride-based group III-V compound semiconductor layer to constitute a channel layer on the second nitride-based group III-V compound semiconductor layer under such a growth temperature condition that the V defects generated in the second nitride-based group III-V compound semiconductor layer are not buried while non-grown regions adjacent to the V defects are generated but additional V defects other than the V defects are not generated; and

forming, on the third nitride-based group III-V compound semiconductor layer, a fourth nitride-based group III-V compound semiconductor layer which becomes a barrier layer having a thin-layer portion formed along the V defects and the non-grown regions adjacent to the V defects, and a flat portion adjoining the thin-layer portion and formed outside the V defects and being thicker than the thin-layer portion, and which constitutes a heterojunction in combination with the third nitride-based group III-V compound semiconductor layer.

According to the manufacturing method of this invention, since the surface-processed portions are formed by patterning the mask material on the substrate, the flatness of the substrate surface can be maintained without the need for etching the substrate. That is, when dry etching of the substrate surface is involved, occurrence of processing roughness on the substrate surface is unavoidable. Also according to this embodiment, it becomes implementable to pattern the surface-processed portions more finely as compared with cases where the surface-processed portions are formed by dry etching process.

In an embodiment, the mask material for selective growth is silicon oxide.

According to the manufacturing method of this embodiment, since silicon oxide (SiO₂) is used as the mask material (surface-processed portions) for selective growth, deposition of GaN less easily occurs on the surface-processed portions, facilitating the selective growth on the surface-processed portions.

In an embodiment, the growth temperature for the first nitride-based group III-V compound semiconductor layer is 1000° C. or higher.

According to the manufacturing method of this embodiment, formation of pits in the first nitride-based group III-V compound semiconductor layer can be prevented.

In an embodiment, the growth temperature for the second nitride-based group III-V compound semiconductor layer is not less than 700° C. and not more than 900° C.

According to the manufacturing method of this embodiment, the V defects can be formed in the second nitride-based group III-V compound semiconductor layer more easily than in cases where the lower limit of the growth temperature is lower than 700° C. or where the upper limit of the growth temperature is higher than 900° C.

In an embodiment, a layer thickness of the second nitride-based group III-V compound semiconductor layer is not more than 100 nm.

According to the manufacturing method of this embodiment, setting the second nitride-based group III-V compound semiconductor layer to a layer thickness of 100 nm or less allows the V defects to be securely generated while regions of poor crystallinity can be made as thin as possible. That is, the low-temperature grown second nitride-based group III-V compound semiconductor layer is poorer in crystallinity than layers (first, third nitride-based group III-V compound semiconductor layers) formed before and after that.

In an embodiment, for the growth of the second nitride-based group III-V compound semiconductor layer, an organic metal having an ethyl group is used as a group-III organometallic material.

According to the manufacturing method of this embodiment, an undesirable phenomenon that the second nitride-based group III-V compound semiconductor layer is internally doped with a large amount of carbon can be avoided. That is, in a case where an organic metal (triethylgallium (TEG) or triethylaluminum (TEA)) having an ethyl group is used to make the second nitride-based group III-V compound semiconductor layer grown at low temperature, an undesirable phenomenon is avoided that the second nitride-based group III-V compound semiconductor layer is internally doped with a large amount of carbon.

In an embodiment, the growth temperature for the third nitride-based group III-V compound semiconductor layer is not less than 950° C. and not more than 1100° C.

According to the manufacturing method of this embodiment, setting the lower-limit temperature of the growth temperature to 950° C. makes it possible to prevent formation of additional V defects in the third nitride-based group III-V compound semiconductor layer even if some pits are generated. Also, setting the upper-limit temperature of the growth temperature to 1100° C. makes it possible to prevent the V defects from being buried by acceleration of the lateral growth.

In this connection, crystal growth of AlGaN, which involves growth temperatures of 1000° C. or higher among nitride-based group III-V compound semiconductors, is performed at growth temperatures similar to those of InGaN, V-shaped non-crystal-grown portions whose nuclei are given by threading dislocations in crystals or stacking faults formed in the crystals, which are so called V defects, are formed. Meanwhile, it has been proved that, for example, GaN that is grown on the patterned sapphire substrate (PSS substrate) forms threading dislocations at vertex portions of the pattern during the fusion of crystals that have extended onto the pattern by lateral growth.

Combining together the above-described two phenomena makes it possible to form the V defects at arbitrary positions. For light emitting elements, these V defects need to be suppressed as much as possible because of their adverse effects such as increases in the leakage current. However, the V defects, which would matter for the light emitting elements, are aggressively utilized for the normally-OFF operation of the transistor in this invention.

In this case, from the viewpoint of preventing extreme degradation of transistor characteristics, it is undesirable that the channel layer is provided by the second nitride-based group III-V compound semiconductor layer alone, in which the V defects are formed. This is because nitride-based group III-V compound semiconductor layers that have been grown at such temperatures as V defects are generated are of poor crystallinity.

Thus, the process includes the steps of making the first nitride-based group III-V compound semiconductor layer grown at such a growth temperature condition that V defects are not generated, subsequently making growth of the second nitride-based group III-V compound semiconductor layer, in which V defects are generated and which is grown to a thickness, and thereafter making the third nitride-based group III-V compound semiconductor layer grown at such a growth temperature condition that generation of V defects is suppressed and that the V defects formed in the second nitride-based group III-V compound semiconductor layer are not buried. Thus, transistor characteristics better than in cases where all the layers are grown at low temperature can be realized.

### Advantgeous Effects of Invention

According to the field effect transistor of the invention, the thin-layer portion of the barrier layer formed by the fourth nitride-based group III-V compound semiconductor layer is formed on the V defects of the second nitride-based group III-V compound semiconductor layer as well as on the non-grown regions of the third nitride-based group III-V compound semiconductor layer adjacent to the V defects. Therefore, according to the invention, the thin-layer portion can be made thinner than the flat portion without etching, and degradation of the channel mobility can be avoided while a state having no etching damage under the gate electrode region is maintained. Thus, a field effect transistor of the normally-OFF operation and prevented from increases in the on-resistance can be realized.

### BRIEF DESCRIPTION OF DRAWINGS

The present invention will become more fully understood from the detailed description given hereinbelow and the accompanying drawings which are given by way of illustration only, and thus are not intended to limit the present invention, and wherein:

FIG. 1 is a perspective view showing a layer structure of a first embodiment of a field effect transistor according to the present invention;

FIG. 2 is a sectional view of a transistor structure of the first embodiment including electrodes;

FIG. 3A is a perspective view for explaining manufacturing process of the field effect transistor of the first embodiment;

FIG. 3B is a perspective view for explaining the manufacturing process;

FIG. 3C is a perspective view for explaining the manufacturing process;

FIG. 3D is a perspective view for explaining the manufacturing process;

FIG. 3E is a perspective view for explaining the manufacturing process;

FIG. 3F is a sectional view for explaining the manufacturing process;

FIG. 4A is a perspective view for explaining manufacturing process of a second embodiment of the field effect transistor according to the invention;

FIG. 4B is a perspective view for explaining the manufacturing process;

FIG. 4C is a perspective view for explaining the manufacturing process;

FIG. 4D is a perspective view for explaining the manufacturing process;

FIG. 4E is a perspective view for explaining the manufacturing process;

FIG. 4F is a perspective view for explaining the manufacturing process;

FIG. 5 is a sectional view of a transistor structure of the second embodiment including electrodes.

### DESCRIPTION OF EMBODIMENTS

Hereinbelow, the present invention will be described in detail by way of embodiments thereof illustrated in the accompanying drawings.

### First Embodiment

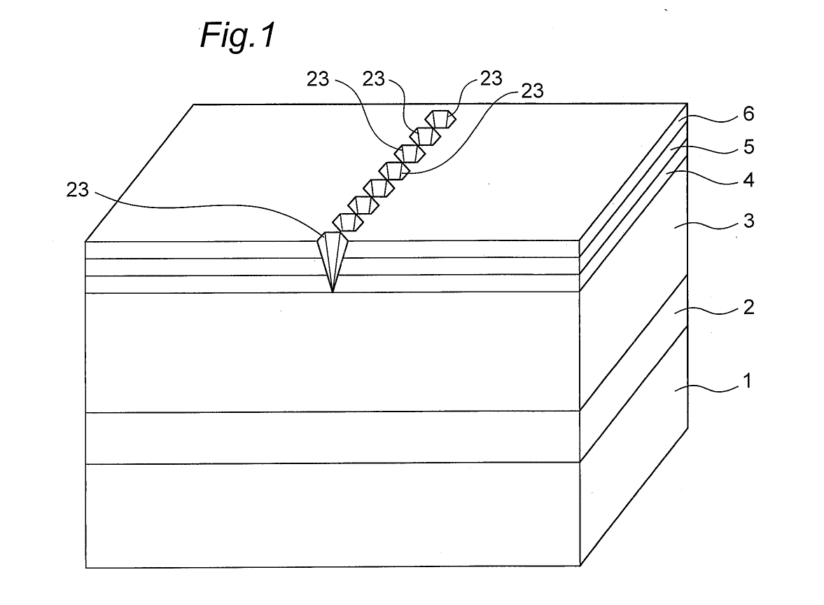

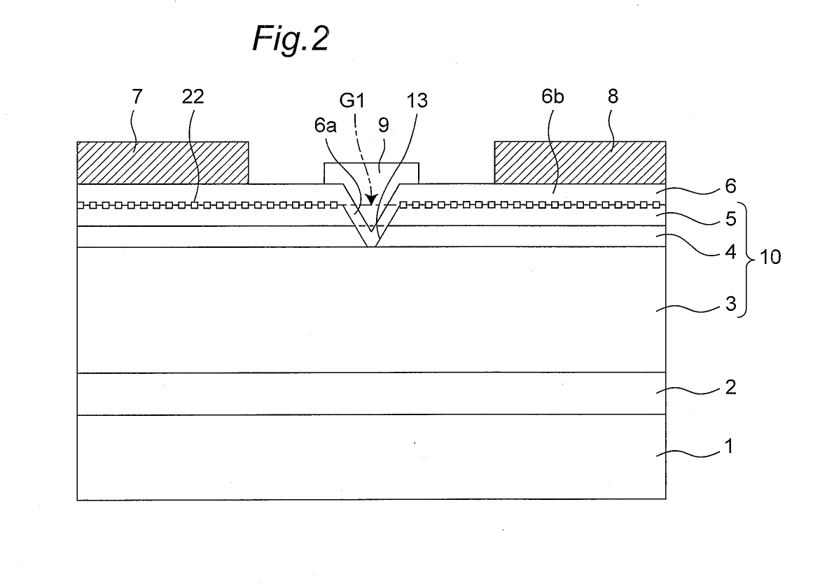

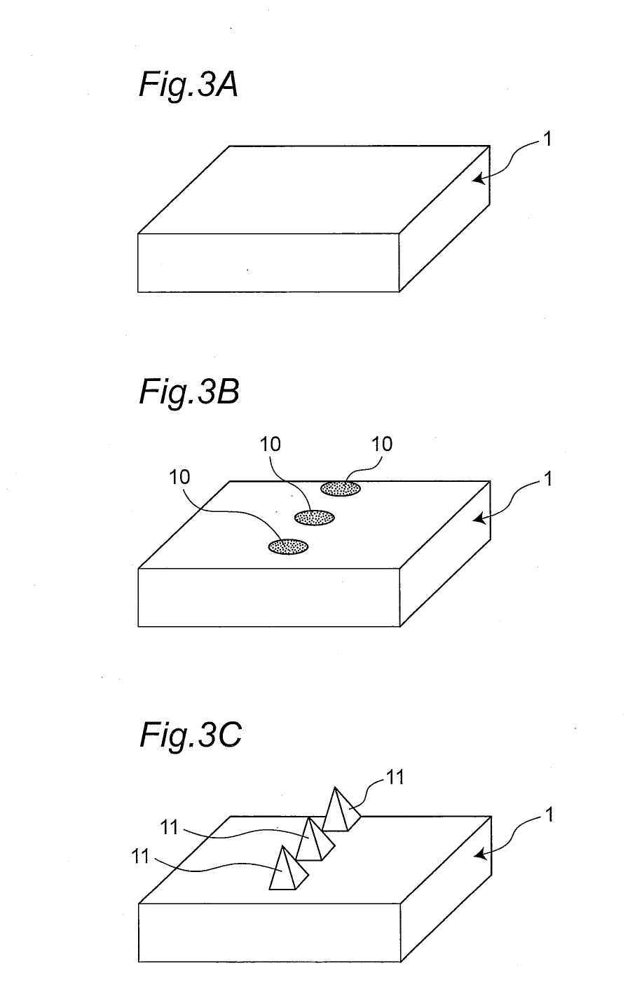

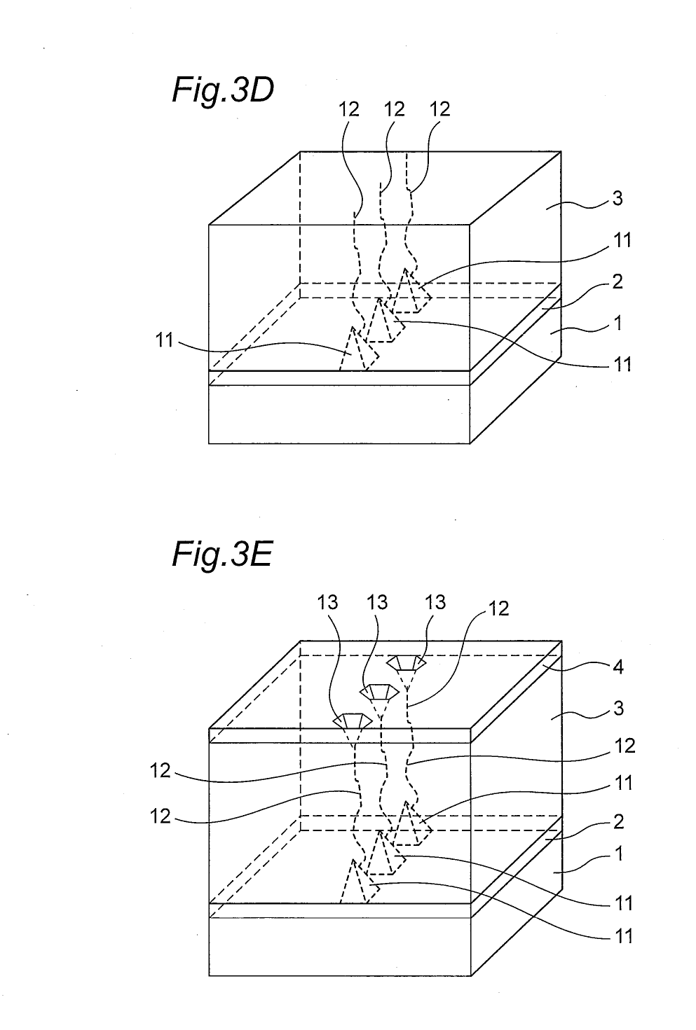

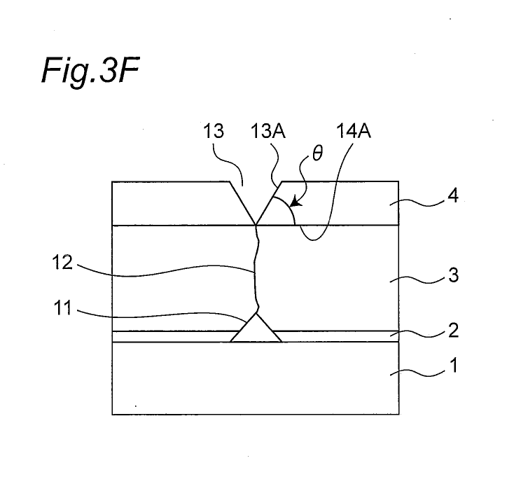

FIG. 1 is a perspective view showing a layer structure of a first embodiment of the field effect transistor according to the invention. FIG. 2 is a sectional view of a transistor structure of the first embodiment including electrodes. FIGS. 3A to 3E and 3F are perspective views and a sectional view for explaining manufacturing process of the field effect transistor according to the first embodiment.

First, manufacturing process of the field effect transistor according to the first embodiment is explained.

First of all, resist or a material having etching-resistant property is applied onto a sapphire substrate 1 shown in FIG. 3A. Next, as shown in FIG. 3B, mask patterns 10 formed of resist and shaped into a plurality of dots are formed by photolithography in regions that come to be under gate electrode. These plural dot-like mask patterns 10 are arrayed in a row with regularity. It is noted that the resist is an AZ-related one having a thickness of 10 μm.

Next, the sapphire substrate 1 is etched by 1 μm by ICP-RIE (Inductively Coupled Plasma-Reactive Ion Etching) using chlorine gas. In this process, the dot-like mask patterns 10 go gradually reduced by heat or the like during the etching. Therefore, by the etching, chevron-shaped protrusive surface-processed portions 11 having roughly pointed edges are formed on the sapphire substrate 1 under the dot-like mask patterns 10 as shown in FIG. 3C.

Next, with TEG (triethylgallium) used as a Ga material gas, as shown in FIG. 3D, a GaN buffer layer 2 of low-temperature growth is grown to a thickness of 50 nm at a substrate temperature of 550° C. on the sapphire substrate 1 that has been surface-processed so that the protrusive surface-processed portions 11 are formed thereon. Thereafter, a first GaN layer 3 as a first nitride-based group III-V compound semiconductor layer is grown to a thickness of 3 μm at a substrate temperature of 1150° C. In this process, the first GaN layer 3 that has become laterally grown from a bottom face kept in contact with the GaN buffer layer 2 on the sapphire substrate 1 has threading dislocations 12 formed in fusion at vertex portions of the protrusive surface-processed portions 11. These threading dislocations 12 never disappear during the growth process, unlike dislocations formed in the bottom face. The first GaN layer 3, by virtue of its growth at the substrate temperature of 1150° C., is also free from occurrence of V defects with the threading dislocations 12 serving as their nuclei. Setting the growth temperature of the first GaN layer 3 to 1000° C. or higher makes it possible to prevent formation of pits in the first GaN layer 3.

Next, as shown in FIG. 3E, a second GaN layer 4 as a second nitride-based group III-V compound semiconductor layer is grown to a thickness of 50 nm at a substrate temperature of 850° C. on the first GaN layer 3. In this process, V defects 13, which are V-shaped non-grown regions with the threading dislocations 12 serving as their nuclei, are formed on the second GaN layer 4. These V defects 13 have an in-plane size of 50 nm/tan 62°≈27 nm as an example. As illustrated in the sectional view of FIG. 3F, an angle θ formed by a bottom face 4A of the second GaN layer 4 and a wall surface 13A that define the V defects 13 was 62° as an example. In addition, making the second GaN layer 4 grown at a substrate temperature of 850° C. allows the V defects 13 to be formed in the second GaN layer 4 more easily than in cases where a lower limit of the substrate temperature is lower than 700° C. or where an upper limit of the substrate temperature is higher than 900° C. Further, setting the second GaN layer 4 to a layer thickness of 100 nm or less allows the V defects 13 to be securely generated while regions of poor crystallinity can be made as thin as possible. That is, the low-temperature grown second GaN layer 4 is poorer in crystallinity than layers (first, third GaN layers 3, 5) formed before and after that.

For the growth of the second GaN layer 4, it is desirable to use an organic metal having an ethyl group as a group-III organometallic material. In this case, an undesirable phenomenon that the second GaN layer 4 is internally doped with a large amount of carbon can be avoided. That is, in a case where an organic metal (triethylgallium (TEG) or triethylaluminum (TEA)) having ethyl groups is used to make the second GaN layer 4 grown at low temperature, there does not occur an undesirable phenomenon that the second GaN layer 4 is internally doped with a large amount of carbon. If an organic metal (trimethylgallium (TMG) or trimethylaluminum (TMA)) having methyl groups should be used to make the second GaN layer 4 grown at low temperature, there would occur an undesirable phenomenon that the second GaN layer 4 is internally doped with a large amount of carbon.

Thereafter, as shown in FIGS. 1 and 2, GaN is grown to a thickness of 1 μm at a substrate temperature of 1000° C. so that the V defects 13 of the second GaN layer 4 are not buried, by which a third GaN layer 5 as a third nitride-based group III-V compound semiconductor layer is formed. This third GaN layer 5 becomes a crystallinity-improving GaN layer. The third GaN layer 5, being grown at a substrate temperature of 1000° C., has the V defects 13 kept unburied and non-grown regions G1 generated in adjacency to the V defects 13, while inhibiting generation of additional V defects other than the V defects 13. Then, by the formation of the third GaN layer 5 on the second GaN layer 4, the in-plane size of extended V defects 23 formed by the V defects 13 and the non-grown regions G1 is enlarged to about 0.56 μm.

In addition, setting the lower-limit temperature of the growth temperature for the third GaN layer 5 to 950° C. makes it possible to prevent formation of additional V defects in the third GaN layer 5 even if some pits are generated. Also, setting the upper-limit temperature of the growth temperature to 1100° C. makes it possible to prevent the V defects 13 from being buried by acceleration of the lateral growth.

Subsequent to this, as shown in FIGS. 1 and 2, an AlGaN barrier layer 6 as a fourth nitride-based group III-V compound semiconductor layer is grown. This AlGaN barrier layer 6 has an Al composition ratio of 25% and a layer thickness of 25 nm. The AlGaN barrier layer 6 has a thin-layer portion 6a which is formed along the V defects 13 and the non-grown regions G1 adjacent to the V defects 13, and a flat portion 6b which is formed adjacent to the thin-layer portion 6a and outside the V defects 13 and which is thicker than the thin-layer portion 6a. In addition, the thickness of the thin-layer portion 6a of the barrier layer 6 is 50% or less of 25 nm that is the thickness of the flat portion 6b as an example.

Thus, a layer structure of this embodiment as shown in the perspective view of FIG. 1 is formed. The AlGaN barrier layer 6 and the third GaN layer 5 constitute a heterojunction, and a two-dimensional electron gas 22 having a concentration of about 8×10¹² cm⁻² is formed at an interface between the flat portion 6b of the AlGaN barrier layer 6 and the third GaN layer 5. Also, the first to third GaN layers 3 to 5 constitute a channel layer 10.

This layer structure of FIG. 1 is patterned with resist to form source/drain electrodes 7 and 8 as shown in FIG. 2. Ohmic electrode metals to form the source/drain electrodes 7, 8 may be Hf/Al/Hf/Au or Ti/Al/Mo/Au. The heat treatment condition to form the source/drain electrodes 7, 8, differing depending on the film thickness of the metal, was set to 1 min. at 800° C. in this embodiment.

Subsequently, a region for deposition of a gate electrode 9 is patterned so that the gate electrode 9 is formed on the AlGaN barrier layer 6. Thus, a field effect transistor of this embodiment is completed as shown in FIG. 2. In addition, while a material of the gate electrode 9 may be Pt, Ni, Pd, WN (Tungsten Nitride) or the like, WN is used in this embodiment.

The transistor formed as described above showed a normally-OFF operation having a pinchoff voltage of 0 V. Also, the thin-layer portion 6a of the barrier layer 6, which is formed on the V defects 13 and the non-grown regions G1 adjacent to the V defects 13, can be made thinner than the flat portion 6b without etching. Therefore, according to this embodiment, increases in the on-resistance can be avoided without causing degradation of the channel mobility due to etching damage.

In this embodiment, the protrusive surface-processed portions 11 are formed by performing dry etching of the sapphire substrate. However, depending on the material of the substrate, wet etching, if allowable, may be performed, and dry etching may be done when the wet etching is hard to do. Also, dry etching and wet etching may be combined together to make use of their advantages. However, in a case where the substrate is made from a nitride-based group III-V compound semiconductor layer such as sapphire, silicon carbide (SiC) or GaN, which is difficult to wet etch with solution, adopting the dry etching allows the substrate to be easily etched. Further, using a chlorine-related gas (chlorine, silicon chloride, boron chloride, etc.) as the etching gas for dry etching makes it possible to implement effective etching for the substrate made from a material which is difficult to wet etch with solution.

### Second Embodiment

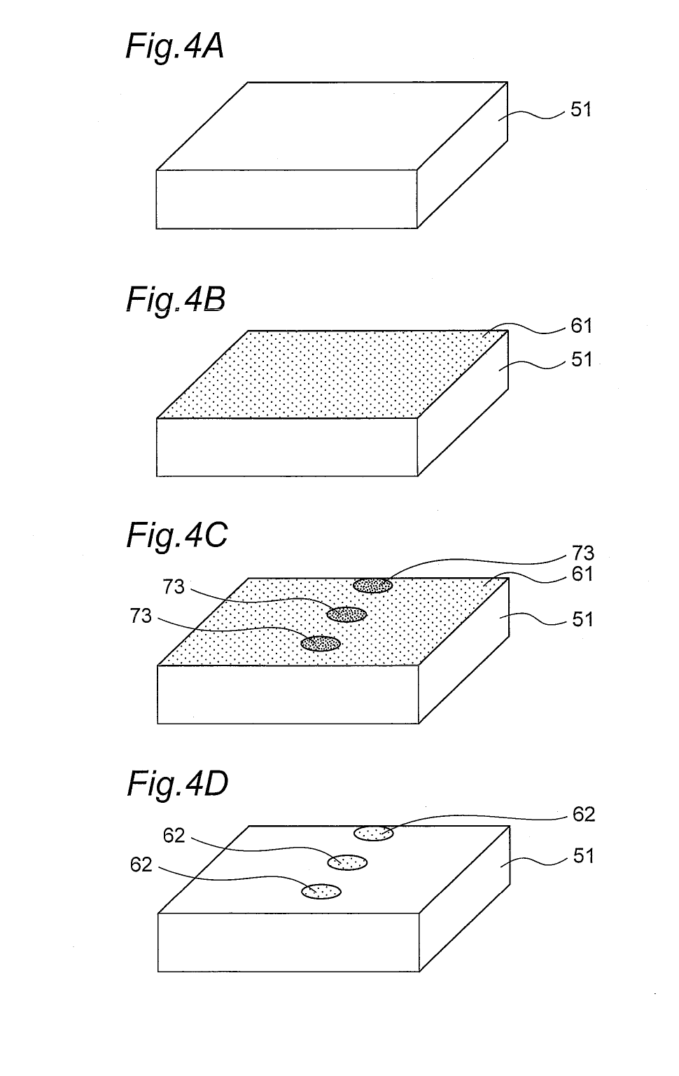

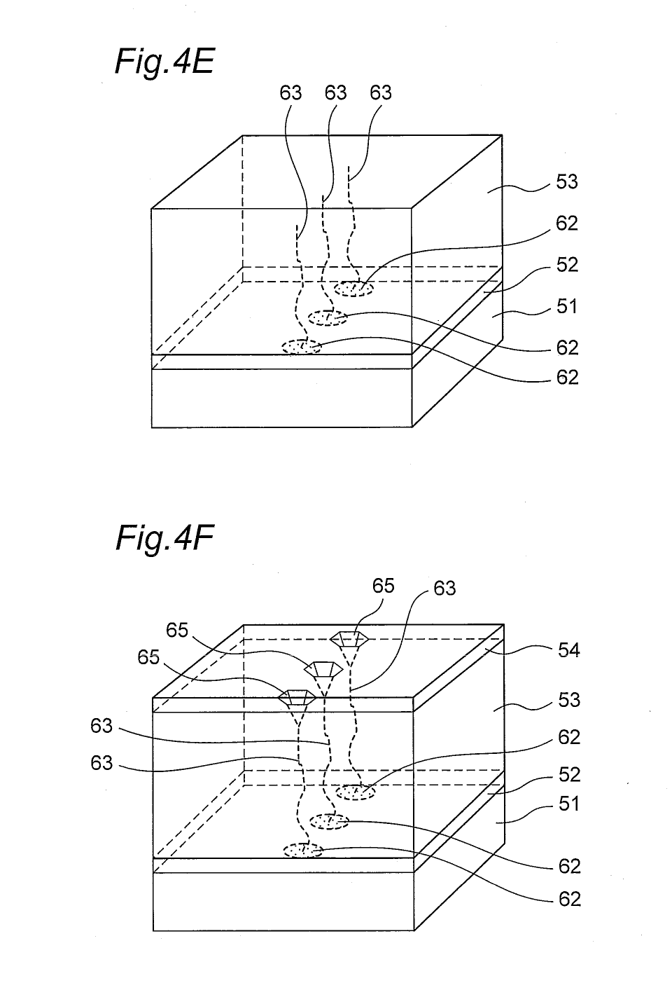

Next, process for manufacturing a second embodiment of the field effect transistor according to the invention is described with reference to the perspective views of FIGS. 4A to 4F sequentially.

First, a 200 nm thick SiO₂ film 61 is formed on a sapphire substrate 51 shown in FIG. 4A by CVD (Chemical Vapor Deposition) process or sputtering process as shown in FIG. 4B. For this process, the film formation process of the SiO₂ film 61 is not particularly limited, and a CVD process, whichever it is thermal CVD process or plasma CVD process, may be used. Also, the film formation process may be sputtering process. In this embodiment, a plasma CVD process using SiH₄ and oxygen was employed as an example of the film formation process for the SiO₂ film 61.

Next, patterning with resist is applied on the SiO₂ film 61, by which mask patterns 73 formed of resist and shaped into a plurality of dots are formed in regions that come to be under gate electrodes as shown in FIG. 4C. These plural dot-like mask patterns 73 are arrayed in a row with regularity. Next, with the mask patterns 73 used as an etching mask, etching by buffered hydrofluoric acid is performed, by which a SiO₂ film 62 is left in a dot-like shape in regions that come to be just under the gate electrodes as shown in FIG. 4D. The dot-like SiO₂ film 62 forms surface-processed portions by a mask material patterned for selective growth on the sapphire substrate 51.

Next, as shown in FIG. 4E, with TEG (triethylgallium) used as a Ga material gas, a GaN buffer layer 52 of low-temperature growth is grown to a thickness of 50 nm at a substrate temperature of 550° C. on the sapphire substrate 51 having the dot-like SiO₂ film 62 left thereon. Thereafter, a first GaN layer 53 as a first nitride-based group III-V compound semiconductor layer is grown to a thickness of 3 μm at a substrate temperature of 1150° C. In this process, the first GaN layer 53 that has become laterally grown from a bottom face kept in contact with the GaN buffer layer 52 on the sapphire substrate 51 has threading dislocations 63 formed in fusion at roughly central portions of the dot-like SiO₂ film 62 as surface-processed portions. These threading dislocations 63 never disappear during the growth process, unlike dislocations formed in the bottom face. The first GaN layer 53, by virtue of its growth at the substrate temperature of 1150° C., is also free from generation of V defects with the threading dislocations 63 serving as their nuclei. Setting the growth temperature of the first GaN layer 53 to 1000° C. or higher makes it possible to prevent formation of pits in the first GaN layer 53.

Next, as shown in FIG. 4F, a second GaN layer 54 as a second nitride-based group III-V compound semiconductor layer is grown to a thickness of 50 nm at a substrate temperature of 850° C. on the first GaN layer 53. As a result, V defects 65, which are V-shaped non-grown regions with the threading dislocations 63 serving as their nuclei are formed on the second GaN layer 54. These V defects 65 have an in-plane size of about 27 nm. In addition, making the second GaN layer 54 grown at a substrate temperature of 850° C. allows the V defects 65 to be formed in the second GaN layer 54 more easily than in cases where the lower limit of the substrate temperature is lower than 700° C. or where the upper limit of the substrate temperature is higher than 900° C.

Further, setting the second GaN layer 54 to a layer thickness of 100 nm or less allows the V defects 65 to be securely generated while regions of poor crystallinity can be made as thin as possible. That is, the low-temperature grown second GaN layer 54 is poorer in crystallinity than layers (first, third GaN layers 53, 55) formed before and after that.

For the growth of the second GaN layer 54, it is desirable to use an organic metal having an ethyl group as a group-III organometallic material. In this case, an undesirable phenomenon that the second GaN layer 54 is internally doped with a large amount of carbon can be avoided. That is, in a case where an organic metal (triethylgallium (TEG) or etriethylaluminum (TEA)) having an ethyl group is used to make the second GaN layer 54 grown at low temperature, there does not occur an undesirable phenomenon that the second GaN layer 54 is internally doped with a large amount of carbon.

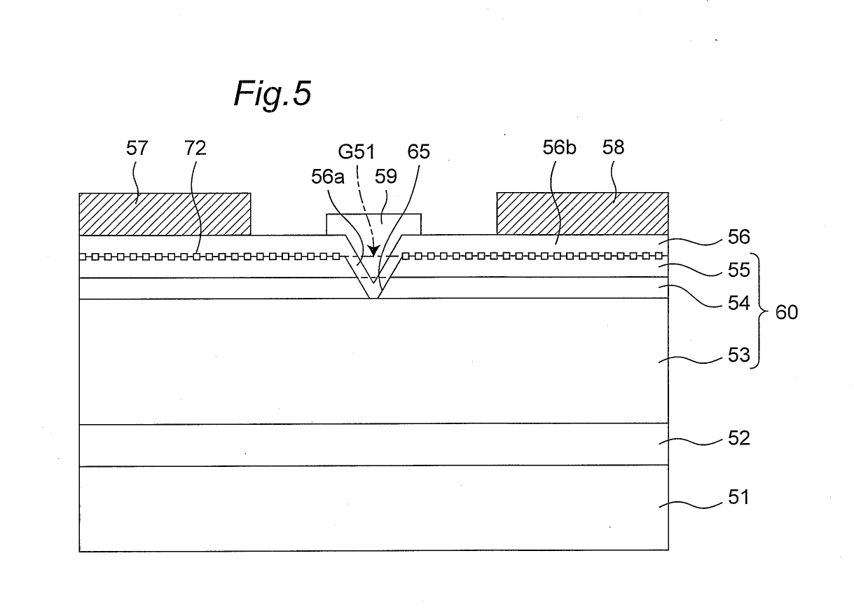

Thereafter, as shown in FIG. 5, GaN is grown to a thickness of 1 μm at a substrate temperature of 1000° C. so that the V defects 65 of the second GaN layer 54 are not buried, by which a third GaN layer 55 as a third nitride-based group III-V compound semiconductor layer is formed. This third GaN layer 55 becomes a crystallinity-improving GaN layer. The third GaN layer 55, being grown at a substrate temperature of 1000° C., has the V defects 13 kept unburied and non-grown regions G51 generated in adjacency to the V defects 65, while inhibiting generation of additional V defects other than the V defects 65. Then, by the formation of the third GaN layer 55 on the second GaN layer 54, the in-plane size of extended V defects formed by the V defects 65 and the non-grown regions G51 is enlarged to about 0.56 μm.

In addition, setting the lower-limit temperature of the growth temperature for the third GaN layer 55 to 950° C. makes it possible to prevent formation of additional V defects in the third GaN layer 55 even if some pits are generated. Also, setting the upper-limit temperature of the growth temperature to 1100° C. makes it possible to prevent the V defects 65 from being buried by acceleration of the lateral growth.

Subsequent to this, an AlGaN barrier layer 56 is grown. This AlGaN barrier layer 56 has an Al composition ratio of 25% and a layer thickness of 25 nm. The AlGaN barrier layer 56 has a thin-layer portion 56a which is formed along the V defects 65 and the non-grown regions G51 adjacent to the V defects 65, and a flat portion 56b which is formed adjacent to the thin-layer portion 56a and outside the V defects 65 and which is thicker than the thin-layer portion 56a.

Thus, a layer structure of this embodiment as shown in the sectional view of FIG. 5 is formed. The AlGaN barrier layer 56 and the third GaN layer 55 constitute a heterojunction, and a two-dimensional electron gas 72 having a concentration of about 8×10¹² cm⁻² is formed at an interface between the flat portion 56b of the AlGaN barrier layer 56 and the third GaN layer 55. Also, the first to third GaN layers 53 to 55 constitute a channel layer 60.

The layer structure shown above is patterned with resist to form source/drain electrodes 57 and 58. Ohmic electrode metals to form the source/drain electrodes 57, 58 may be Hf/Al/Hf/Au or Ti/Al/Mo/Au. The heat treatment condition to form the source/drain electrodes 57, 58, differing depending on the film thickness of the metal, was set to 1 min. at 800° C. in this embodiment.

Subsequently, a region for deposition of a gate electrode 59 is patterned so that the gate electrode 59 is formed on the AlGaN barrier layer 56. Thus, a field effect transistor of this embodiment is completed as shown in FIG. 5. In addition, while a material of the gate electrode 59 may be Pt, Ni, Pd, WN or the like, WN is used in this embodiment.

The transistor formed as described above showed a normally-OFF operation having a pinchoff voltage of 0 V. Also, the thin-layer portion 56a of the barrier layer 56, which is formed on the V defects 65 and the non-grown regions G51 adjacent to the V defects 65, can be made thinner than the flat portion 56b without etching. Therefore, according to this embodiment, increases in the on-resistance can be avoided without causing degradation of the channel mobility due to etching damage. Also according to the transistor manufacturing method described above, since the dot-like SiO₂ film 62 as surface-processed portions is formed by patterning of the mask material SiO₂ on the sapphire substrate 51, the flatness of the substrate surface can be maintained without the need for etching the substrate 51. That is, when dry etching of the substrate surface is involved, occurrence of processing roughness on the surface of the substrate 51 is unavoidable. Also according to the manufacturing method, it becomes implementable to pattern the surface-processed portions more finely as compared with cases where the surface-processed portions are formed by dry etching process. Besides, since silicon oxide (SiO₂) is used as the mask material for selective growth of the dot-like SiO₂ film 62 as the surface-processed portions, deposition of GaN less occurs on the dot-like SiO₂ film 62, facilitating the selective growth on the dot-like SiO₂ film 62.

The substrate is provided by a sapphire substrate in this embodiment. However, the substrate may also be provided by a nitride-based group III-V compound semiconductor layer of silicon carbide (SiC) or GaN or the like.

### Third Embodiment

A third embodiment of the invention includes the following process added to the above-described first or second embodiment. That is, before the formation of the gate electrode 9, 59 on the AlGaN barrier layer 6, 56, a gate insulating film (not shown) of SiO₂ (thickness: 10 nm) is deposited on the AlGaN barrier layer 6, 56, and thereafter the gate electrode 9, 59 is deposited. By this process, an MIS type FET as this third embodiment can be manufactured. Manufacturing conditions for the third embodiment are similar to the manufacturing conditions described in the foregoing first or second embodiment except for manufacturing SiO₂ that forms the gate insulating film.

According to the third embodiment, since the gate insulating film is formed, the pinchoff voltage can be increased as compared with cases where the gate insulating film is not formed. Thus, the third embodiment is suitable for circuit applications. In one example, with the gate insulating film formed, the pinchoff voltage increased to about +3 V, making it possible to achieve a more desirable normally-OFF operation.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### REFERENCE SIGNS LIST

1, 51 . . . sapphire substrate
2, 52 . . . GaN buffer layer of low-temperature growth
3, 53 . . . first GaN layer
4 . . . second GaN layer
5 . . . third GaN layer
6, 56 . . . AlGaN barrier layer
6a, 56a . . . thin-layer portion
6b, 56b . . . flat portion
7, 8, 57, 58 . . . source/drain electrode
9, 59 . . . gate electrode
10, 60 . . . channel layer
11 . . . protrusive surface-processed portion
12, 63 . . . threading dislocation
13, 65 . . . V defect
13A . . . wall surface
22, 72 . . . two-dimensional electron gas
23 . . . extended V defects
G1, G51 . . . non-grown region
61 . . . SiO₂ film
62 . . . dot-like SiO₂ film

1. A field effect transistor comprising:
a substrate having surface-processed portions formed at predetermined places in a surface thereof;
a buffer layer formed on the substrate;
a first nitride-based group III-V compound semiconductor layer which is formed on the buffer layer and which has dislocations generated at places corresponding to the surface-processed portions but has no V defects that are V-shaped non-grown regions whose nuclei are given by the dislocations;
a second nitride-based group III-V compound semiconductor layer formed on the first nitride-based group III-V compound semiconductor layer and having V defects that are V-shaped non-grown regions whose nuclei are given by the dislocations;
a third nitride-based group III-V compound semiconductor layer which is formed on the second nitride-based group III-V compound semiconductor layer so that the V defects are not buried thereby and which has non-grown regions adjacent to the V defects but has no additional V defects other than the V defects; and
a fourth nitride-based group III-V compound semiconductor layer which is formed on the third nitride-based group III-V compound semiconductor layer and which has a thin-layer portion formed along the V defects and the non-grown regions adjacent to the V defects, and a flat portion adjoining the thin-layer portion and formed outside the V defects and being thicker than the thin-layer portion, wherein
the first to third nitride-based group III-V compound semiconductor layers constitute a channel layer, the fourth nitride-based group III-V compound semiconductor layer constitutes a barrier layer, and the third nitride-based group III-V compound semiconductor layer and the fourth nitride-based group III-V compound semiconductor layer constitute a heterojunction.

2. The field effect transistor as claimed in claim 1, wherein
the V defects are arrayed with regularity.

3. The field effect transistor as claimed in claim 2, further comprising
a gate electrode formed on the V defects arrayed with regularity.

4. The field effect transistor as claimed in claim 1, further comprising
an insulating film formed between the fourth nitride-based group III-V compound semiconductor layer and the gate electrode.

5. A field effect transistor manufacturing method comprising the steps of:
forming a mask pattern on a substrate with resist or a material having etching-resistant property;
forming protrusive surface-processed portions at predetermined portions of the substrate by etching portions out of the substrate that are not covered with the mask pattern;
subsequently forming a buffer layer on the substrate;
making growth of a first nitride-based group III-V compound semiconductor layer that constitutes a channel layer on the buffer layer under such a growth temperature condition that dislocations are generated from places corresponding to the protrusive surface-processed portions while V defects that are V-shaped non-grown regions whose nuclei are given by the dislocations are not generated;
making growth of a second nitride-based group III-V compound semiconductor layer to constitute a channel layer under such a growth temperature condition that the V defects are generated on the first nitride-based group III-V compound semiconductor layer;
making growth of a third nitride-based group III-V compound semiconductor layer to constitute a channel layer on the second nitride-based group III-V compound semiconductor layer under such a growth temperature condition that the V defects of the second nitride-based group III-V compound semiconductor layer are not buried while non-grown regions adjacent to the V defects are generated but additional V defects other than the V defects are not generated; and
forming, on the third nitride-based group III-V compound semiconductor layer, a fourth nitride-based group III-V compound semiconductor layer which becomes a barrier layer having a thin-layer portion formed along the V defects and the non-grown regions adjacent to the V defects, and a flat portion adjoining the thin-layer portion and formed outside the V defects and being thicker than the thin-layer portion, and which constitutes a heterojunction in combination with the third nitride-based group III-V compound semiconductor layer.

6. The field effect transistor manufacturing method as claimed in claim 5, wherein
a process of etching the substrate is implemented by dry etching or wet etching, or a combination of dry etching and wet etching.

7. The field effect transistor manufacturing method as claimed in claim 6, wherein
given that the substrate is made from a hard-to-wet etch material, the substrate is etched by dry etching.

8. The field effect transistor manufacturing method as claimed in claim 7, wherein
an etching gas used for the dry etching is a chlorine-related gas.

9. A field effect transistor manufacturing method comprising the steps of:
patterning a mask material for selective growth on a substrate to form surface-processed portions of the patterned mask material at predetermined places on the substrate;
subsequently forming a buffer layer on the substrate;
making growth of a first nitride-based group III-V compound semiconductor layer that constitutes a channel layer on the buffer layer under such a growth temperature condition that dislocations are generated from places corresponding to the surface-processed portions while V defects that are V-shaped non-grown regions whose nuclei are given by the dislocations are not generated;
making growth of a second nitride-based group III-V compound semiconductor layer to constitute a channel layer on the first nitride-based group III-V compound semiconductor layer under such a growth temperature condition that the V defects are generated;
making growth of a third nitride-based group III-V compound semiconductor layer to constitute a channel layer on the second nitride-based group III-V compound semiconductor layer under such a growth temperature condition that the V defects generated in the second nitride-based group III-V compound semiconductor layer are not buried while non-grown regions adjacent to the V defects are generated but additional V defects other than the V defects are not generated; and
forming, on the third nitride-based group III-V compound semiconductor layer, a fourth nitride-based group III-V compound semiconductor layer which becomes a barrier layer having a thin-layer portion formed along the V defects and the non-grown regions adjacent to the V defects, and a flat portion adjoining the thin-layer portion and formed outside the V defects and being thicker than the thin-layer portion, and which constitutes a heterojunction in combination with the third nitride-based group III-V compound semiconductor layer.

10. The field effect transistor manufacturing method as claimed in claim 9, wherein
the mask material for selective growth is silicon oxide.

11. The field effect transistor manufacturing method as claimed in claim 5, wherein
the growth temperature for the first nitride-based group III-V compound semiconductor layer is 1000° C. or higher.

12. The field effect transistor manufacturing method as claimed in claim 5, wherein
the growth temperature for the second nitride-based group III-V compound semiconductor layer is not less than 700° C. and not more than 900° C.

13. The field effect transistor manufacturing method as claimed in claim 12, wherein
a layer thickness of the second nitride-based group III-V compound semiconductor layer is not more than 100 nm.

14. The field effect transistor manufacturing method as claimed in claim 5, wherein
for the growth of the second nitride-based group III-V compound semiconductor layer, an organic metal having an ethyl group is used as a group-III organometallic material.

15. The field effect transistor manufacturing method as claimed in claim 5, wherein
the growth temperature for the third nitride-based group III-V compound semiconductor layer is not less than 950° C. and not more than 1100° C.

16. The field effect transistor manufacturing method as claimed in claim 9, wherein
the growth temperature for the first nitride-based group III-V compound semiconductor layer is 1000° C. or higher.

17. The field effect transistor manufacturing method as claimed in claim 9, wherein
the growth temperature for the second nitride-based group III-V compound semiconductor layer is not less than 700° C. and not more than 900° C.

18. The field effect transistor manufacturing method as claimed in claim 7, wherein
a layer thickness of the second nitride-based group III-V compound semiconductor layer is not more than 100 nm.

19. The field effect transistor manufacturing method as claimed in claim 9, wherein
for the growth of the second nitride-based group III-V compound semiconductor layer, an organic metal having an ethyl group is used as a group-III organometallic material.

20. The field effect transistor manufacturing method as claimed in claim 9, wherein
the growth temperature for the third nitride-based group III-V compound semiconductor layer is not less than 950° C. and not more than 1100° C.
